(19) United States
(12) Patent Application Publication
(10) Pub. No.: US 2026/0271498 A1
(43) Pub. Date: Sep. 10, 2026

(54) DISPLAY DEVICE INCLUDING QUANTUM LAYER AND METHOD FOR MANUFACTURING THE SAME

(71) Applicants: SAMSUNG DISPLAY CO., LTD., YONGIN-SI (KR); Research & Business Foundation SUNGKYUNKWAN UNIVERSITY, Suwon-Si (KR)

(72) Inventors: Byung Han YOO, Yongin-si (KR); Jung Woo PARK, Yongin-si (KR); So Hee JEONG, Suwon-Si (KR); Dae Kwon SHIN, Suwon-Si (KR); Young Sang PARK, Suwon-Si (KR)

(21) Appl. No.: 19/404,340

(22) Filed: Dec. 1, 2025

(30) Foreign Application Priority Data
Mar. 6, 2025 (KR) 10-2025-0028914
Mar. 31, 2025 (KR) 10-2025-0041225

(51) Int. Cl. H10K 50/115; H10K 50/16; H10K 50/17; H10K 59/12

(52) U.S. Cl. CPC H10K 50/115; H10K 50/166; H10K 50/171; H10K 59/1201

(57) ABSTRACT

A display device includes a substrate including a first area and a second area. A first electrode is disposed in the first and second areas. A first electron transport layer is disposed in the first area on the first electrode. A quantum layer is disposed in the first area on the first electron transport layer. A hole layer is disposed in the first area on the quantum layer and the second area on the first electrode. A light emitting layer is disposed in the second area on the hole layer. An electron layer is disposed in the first area on the hole layer and the second area on the light emitting layer. A second electrode is disposed in the first area and the second area on the electron layer. The quantum layer includes a first quantum dot of N type and a second quantum dot of P type.

### CROSS-REFERENCE TO RELATED APPLICATION

This application claims priority under 35 U.S.C. 119 to Korean Patent Application No. 10-2025-0028914 filed on Mar. 06, 2025, and Korean Patent Application No. 10-2025-0041225 filed on Mar. 31, 2025, in the Korean Intellectual Property Office, the contents of which are herein incorporated by reference in their entirety.

### TECHNICAL FIELD

The present disclosure relates to a display device, and more specifically, to a display device including a quantum layer and a method for manufacturing the same.

### DISCUSSION OF THE RELATED ART

With the advancement of the information age, the demand for a display device for displaying an image of various forms has increased. For example, the display device has been applied to various electronic devices such as a smart phone, a digital camera, a laptop computer, a vehicle navigation system, and a smart television.

The display device may be a flat panel display device such as a liquid crystal display device, a field emission display device and a light emitting display device. The light emitting display device may include an organic light emitting display device that includes an organic light emitting element, an inorganic light emitting display device that includes an inorganic light emitting element such as an inorganic semiconductor, and a micro light emitting display device that includes a micro light emitting element.

The organic light emitting display device displays an image by using light emitting elements, each of which includes a light emitting layer of an organic light emitting material. As the organic light emitting display device produces the displayed image by using a self-light emitting element, the organic light emitting display device may have excellent performance in view of power consumption, response speed, light emitting efficiency, luminance and wide viewing angle as compared with the other display devices.

Quantum dots are nanoscale crystals made from semiconductor material that exhibit a phenomenon called the quantum confinement effect. Because of this effect, colloidal quantum dots have size-dependent band gaps, meaning their optical and electronic properties change with their size. These properties make them useful for various applications, including light-emitting devices like QD-TVs, QD-LEDs, and QD-displays, as well as light-absorbing devices such as QD-photodetectors and QD-solar cells.

### SUMMARY

A display device includes a substrate including a first area and a second area. A first electrode is disposed in the first area and the second area on the substrate. A first electron transport layer is disposed in the first area on the first electrode. A quantum layer is disposed in in the first area on the first electron transport layer. A hole layer is disposed in the first area on the quantum layer and the second area on the first electrode. A light emitting layer is disposed in the second area on the hole layer. An electron layer is disposed in the first area on the hole layer and the second area on the light emitting layer. A second electrode is disposed in the first area and the second area on the electron layer. The quantum layer includes a first quantum dot of N type and a second quantum dot of P type.

The quantum layer may include a first quantum layer including the first quantum dot, and a second quantum dot layer disposed on the first quantum layer, including the second quantum dot.

The quantum layer may be configured to absorb light having a wavelength of 600 nm to 950 nm and convert the absorbed light into an electrical signal.

The quantum layer may have external quantum efficiency of 40% or more at a wavelength of 600 nm to 950 nm.

The first quantum dot and the second quantum dot may include a ligand, and the ligand may include halogen, a thiol group, a hydroxyl group, or a carboxyl group.

Each of the first quantum dot and the second quantum dot may include at least one of indium arsenide (InAs), indium antimonide (InSb), lead sulfide (PbS), or silver telluride (Ag₂Te).

The first quantum dot or the second quantum dot may be doped with a dopant.

The first area may be a light receiving portion that absorbs light having a wavelength of 600 nm to 950 nm, and the second area may be a light emitting portion that emits light.

The second area may emit light having a wavelength of 350 nm to 800 nm.

The first area may be a non-display area, and the second area may be a display area.

The hole layer may include a hole injection layer and a hole transport layer disposed on the hole injection layer.

The electron layer may include a second electron transport layer and an electron injection layer disposed on the second electron transport layer.

The display device may further including a buffer layer disposed between the electron layer and the hole layer.

A method for manufacturing a display device includes forming a first electrode in a first area and a second area of a substrate. A first electron transport layer is formed in the first area on the first electrode. A quantum layer is formed in the first area on the first electron transport layer. A hole layer is formed in the first area on the quantum layer and the second area on the first electrode. A light emitting layer is formed in the second area on the hole layer. An electron layer is formed in the first area on the hole layer and the second area on the light emitting layer. A second electrode is formed in the first area and the second area on the electron layer. The quantum layer includes a first quantum dot of N type and a second quantum dot of P type.

The forming of the quantum layer may include forming a first quantum layer including the first quantum dot and forming a second quantum dot layer including the second quantum dot on the first quantum layer.

The first quantum dot and the second quantum dot may each include a ligand, and the ligand may include halogen, a thiol group, a hydroxyl group, or a carboxyl group.

An electronic device includes a display device displaying an image and a processor transmitting an image data signal to the display device. The display device includes a substrate including a first area and a second area. A first electrode is disposed in the first area and the second area on the substrate. A first electron transport layer is disposed in the first area on the first electrode. A quantum layer is disposed in the first area on the first electron transport layer. A hole layer is disposed in the first area on the quantum layer and the second area on the first electrode. A light emitting layer is disposed in the second area on the hole layer. An electron layer is disposed in the first area on the hole layer and the second area on the light emitting layer. A second electrode is disposed in the first area and the second area on the electron layer. The quantum layer includes a first quantum dot of N type and a second quantum dot of P type.

The quantum layer may include a first quantum layer including the first quantum dot, and a second quantum dot layer disposed on the first quantum layer, including the second quantum dot.

The first quantum dot and the second quantum dot may include a ligand, and the ligand may include halogen, a thiol group, a hydroxyl group, or a carboxyl group.

The first area may be a non-display area, and the second area may be a display area.

### BRIEF DESCRIPTION OF THE DRAWINGS

The above and other aspects and features of the present disclosure will become more apparent by describing in detail exemplary embodiments thereof with reference to the attached drawings, in which:

FIG. 1 is a plan view illustrating a display device according to an embodiment;

FIG. 2 is a cross-sectional view illustrating A-A’ of FIG. 1;

FIG. 3 is a cross-sectional view illustrating a display panel according to an embodiment;

FIG. 4 is an enlarged cross-sectional view illustrating an area of a light receiving portion PD of FIG. 3;

FIG. 5 is an enlarged cross-sectional view illustrating an area of a light emitting element LE of FIG. 3;

FIG. 6 is an enlarged cross-sectional view illustrating an area of a light receiving portion PD of the second embodiment of FIG. 3;

FIG. 7 is a graph illustrating electrical characteristics when a first quantum dot is applied to a field effect transistor;

FIG. 8 is a graph illustrating electrical characteristics when a second quantum dot is applied to a field effect transistor;

FIG. 9 is a graph illustrating electrical characteristics when light is directed to a light receiving portion of Comparative Example 1, Comparative Example 2, and Example 1;

FIG. 10 is a graph illustrating external quantum efficiency (EQE) according to a wavelength of Example 1 manufactured in accordance with the embodiment;

FIG. 11 is a block diagram illustrating an electronic device according to an embodiment; and

FIG. 12 illustrate schematic diagrams of electronic devices according to various embodiments.

### DETAILED DESCRIPTION

Aspects and features of the present invention, and the methods for achieving them, will become clear with reference to the embodiments described below in detail with the accompanying drawings. However, the present invention is not necessarily limited to the embodiments disclosed below, but may be implemented in various different forms, and these embodiments are provided only to make the disclosure of the present invention complete and to fully inform those skilled in the art of the invention of the scope of the invention.

When elements or layers are referred to as "on" another element or layer, this includes all cases where another layer or another element is interposed directly over or in the middle of the other element. The same reference numerals may refer to the same components throughout the specification and the figures. While each drawing may represent one or more particular embodiments of the present disclosure, drawn to scale, such that the relative lengths, thicknesses, and angles can be inferred therefrom, it is to be understood that the present invention is not necessarily limited to the relative lengths, thicknesses, and angles shown. Changes to these values may be made within the spirit and scope of the present disclosure, for example, to allow for manufacturing limitations and the like. Although the terms "first" and "second" are used to describe various components, these components are not necessarily limited by these terms. These terms are used to distinguish one component from another. Therefore, the first component mentioned below may be the second component within the technical idea of the present invention. The features of each of the various embodiments of the present invention may be partially or wholly combined or combined with each other, and various technical connections and operations are possible, and each embodiment may be implemented independently of each other or may be implemented together in a related relationship.

Embodiments of the present disclosure relate to a display device capable of both displaying images and sensing near-infrared light. The device includes a substrate with a designated display area and a non-display area. In the display area, a conventional light-emitting stack is formed with a first electrode, hole layer, light-emitting layer, electron layer, and a second electrode, producing visible light for image display. In the non-display area, a light-receiving portion is constructed using a layered quantum dot structure. This structure comprises a first electron transport layer, a quantum layer made from N-type and P-type quantum dots, and a similar hole and electron stack above, capped with a shared second electrode. The quantum layer, positioned between the transport layers, absorbs infrared light and converts it into electrical signals, effectively acting as a built-in proximity or infrared sensor.

The quantum layer is made from two types of quantum dots: an N-type and a P-type, which may be layered or mixed. These quantum dots are chemically tuned through ligand exchange to improve conductivity and doping characteristics. Examples of materials include indium arsenide (InAs), lead sulfide (PbS), and other semiconductors suitable for light absorption in the 600–950 nm range. The layered quantum dots form a p-n junction, giving the light-receiving area diode-like behavior. The shared use of the hole and electron layers for both light-emitting and light-receiving regions reduces fabrication complexity and cost, as both functions are built into the same vertical layer structure.

By integrating this light-sensing function into the display’s non-emissive areas, the device can incorporate features like proximity sensing without requiring additional external sensors or stacked layers. The result is a compact, multifunctional display suited for a wide range of electronic devices including smartphones, tablets, wearables, and automotive interfaces. The simplified structure also improves manufacturability and enhances the display’s overall functionality and design flexibility.

Hereinafter, detailed embodiments will be described with reference to the accompanying drawings.

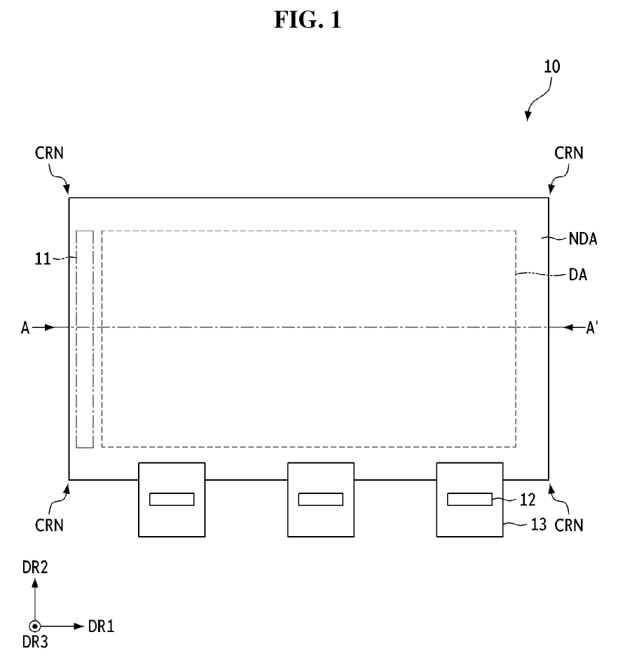

FIG. 1 is a plan view illustrating a display device according to an embodiment.

Referring to FIG. 1, a display device 10, according to an embodiment, is a device that displays a moving image or a still image, and may be used as a display screen of various electronic devices such as a television, a laptop/notebook computer, a computer monitor, an advertising board and an Internet of things (IoT) device as well as portable electronic devices such as a mobile phone, a smart phone, a tablet computer, a smart watch, a watch phone, a mobile communication terminal, an electronic diary, an electronic book, a portable multimedia player (PMP), a vehicle navigation system, and an ultra mobile PC (UMPC).

The display device 10 may be a light emitting display device such as an organic light emitting display device using an organic light emitting diode, a quantum dot light emitting display device including a quantum dot light emitting layer, an inorganic light emitting display device including an inorganic semiconductor and a micro or nano light emitting display device using a micro or nano light emitting diode (micro LED or nano LED). The following description will be based on the display device 10 being a quantum dot light emitting display device, but the present disclosure is not necessarily limited thereto and may be applied to an organic light emitting display device, an inorganic light emitting display device or a micro or nano light emitting display device.

The display device 10 may be flat, but is not necessarily limited thereto. For example, the display device 10 may include a curved portion formed at left and right ends, having a constant curvature or a variable curvature. In addition, the display device 10 may be flexibly formed to be curved, twisted, bent, folded or rolled.

According to an embodiment, the display device 10 may be an organic light emitting display device.

As shown in FIG. 1, the display device 10, according to embodiments, may include one surface of a rectangular shape, but this is only an example, and the shape of the display device 10 is not necessarily limited to the example shown in FIG. 1. For example, the display device 10, according to embodiments, may include one surface of a polygonal shape or a circular shape in addition to the rectangular shape. Alternatively, at least a portion of the display device 10 may be modified from an unfolded state to a curved, twisted, bent, folded, or rolled state.

One surface of the display device 10 may include a display area DA through which light for image display is emitted, and a non-display area NDA surrounding the periphery of the display area DA.

The display area DA may occupy the majority of one surface of the display device 10.

The non-display area NDA does not emit light for image display, and may be a frame shape surrounding the periphery of the display area DA. For example, the non-display area NDA may be of a specific color such as black and may constitute a bezel area of the display device.

One surface of the display device 10 may include corners CRN in which sides in crossing directions are in contact with each other. As an example, when one surface of the display device 10 has a rectangular shape, it may include four corners CRN.

The display device 10 may include drivers 11 and 12 that transmit a signal, a voltage, or a power source to light emitting pixel drivers in the display area DA.

A portion 11 of the drivers 11 and 12, which may be implemented as a relatively simple circuit, may be disposed in the non-display area NDA.

The other portion 12 of the drivers 11 and 12 may be provided as an integrated circuit chip, and may be mounted on the circuit board 13 electrically connected to pads of the non-display area NDA. Alternatively, the other portion 12 of the driver 12 may be mounted on the pads in the non-display area NDA.

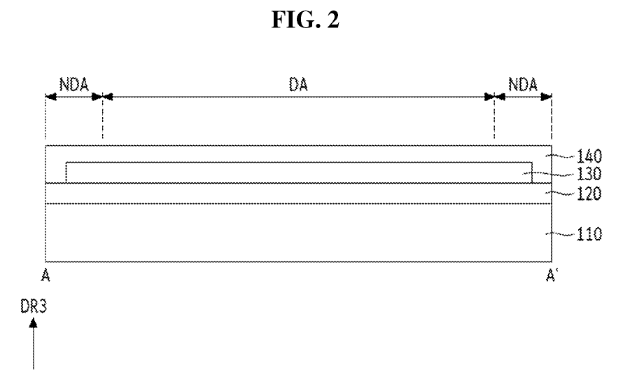

FIG. 2 is a cross-sectional view taken along line A-A’ of FIG. 1.

Referring to FIG. 2, the display device 10, according to an embodiment, may include a display area DA through which light for image display is emitted, and a non-display area NDA disposed around the display area DA that does not emit light.

According to an embodiment, the display device 10 may include a substrate 110 including a display area DA and a non-display area NDA, and a circuit layer 120, an element layer 130, and an encapsulation layer 140, which are disposed on the substrate 110.

The element layer 130 may be disposed on the circuit layer 120.

For example, according to an embodiment, the display device 10 may include a substrate 110, a circuit layer 120 disposed on the substrate 110, an element layer 130 disposed on the circuit layer 120, and an encapsulation layer 140 disposed on the element layer 130.

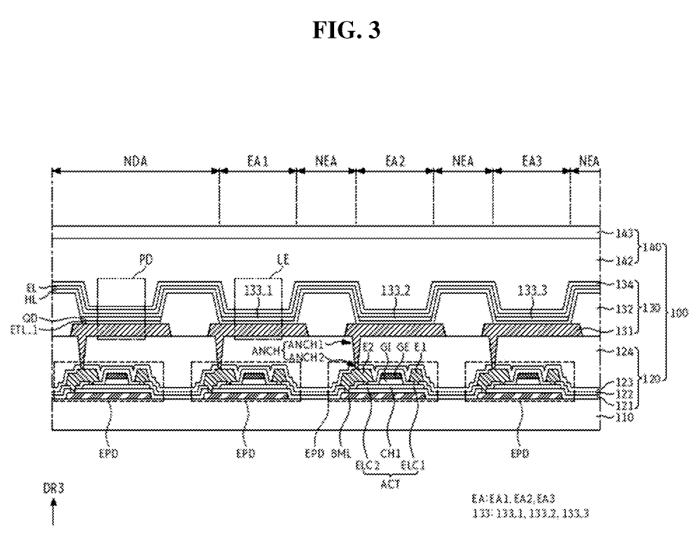

FIG. 3 is a cross-sectional view illustrating a display panel according to an embodiment.

Referring to FIG. 3, the display device 10 may include a substrate 110, a circuit layer 120 disposed on the substrate 110, an element layer 130 including light emitting elements LE in light emission areas EA on the circuit layer 120, and an encapsulation layer 140 covering the element layer 130. Light emitted from the light emitting elements LE of the element layer 130 may pass through the encapsulation layer 140.

The substrate 110 may include a display area (DA of FIG. 1) and a non-display area (NDA of FIG. 1).

The display area DA may include light emission areas EA1, EA2 and EA3 (EA of FIG. 3) arranged in parallel and a non-light emission area NEA disposed between the light emission areas EA1, EA2 and EA3 (EA of FIG. 3).

The circuit layer 120 may include a buffer layer 121 on the substrate 110, a first interlayer insulating layer 122 on the buffer layer 121, a second interlayer insulating layer 123 on the first interlayer insulating layer 122, and a planarization layer 124 on the second interlayer insulating layer 123.

Each of the buffer layer 121, the first interlayer insulating layer 122, and the second interlayer insulating layer 123 may include an inorganic insulating material.

The planarization layer 124 may include an organic insulating material.

The circuit layer 120 may include light emitting pixel drivers EPD that transmit a driving current to the light emitting elements LE.

Each of the light emitting pixel drivers EPD may include two or more transistors, and may be electrically connected to one or more lines.

A first transistor ST1 of each of the light emitting pixel drivers EPD may include an active layer ACT on the buffer layer 121, a gate insulating layer GI covering a channel portion CH1 of the active layer ACT, a gate electrode GE on the gate insulating layer GI, and a first transistor electrode E1 and a second transistor electrode E2, which are on the first interlayer insulating layer 122 covering the active layer ACT and the gate electrode GE.

At least the channel portion CH1 of the active layer ACT may overlap a light blocking layer BML on the substrate 110.

The buffer layer 121 may cover the light blocking layer BML.

The active layer ACT may include a channel portion CH1, a first transistor electrode portion ELC1 connected to one side of the channel portion CH1, and a second transistor electrode portion ELC2 connected to the other side of the channel portion CH1.

The first transistor electrode E1 may be electrically connected to the first transistor electrode portion ELC1 of the active layer ACT through a hole passing through the first interlayer insulating layer 122.

The second transistor electrode E2 may be electrically connected to the second transistor electrode portion ELC2 of the active layer ACT through the hole passing through the first interlayer insulating layer 122.

The second transistor electrode E2 may be electrically connected to the light blocking layer BML through a hole passing through the first interlayer insulating layer 122 and the buffer layer 121.

An upper surface of the channel portion CH1 may face the gate electrode GE, and a rear surface of the channel portion CH1 may face the light blocking layer BML electrically connected to the second transistor electrode E2.

Accordingly, a portion of the active layer ACT, which is adjacent to the light blocking layer BML, may be activated in a relatively weak manner as compared to another portion adjacent to the gate electrode GE depending on the same potential of the light blocking layer BML as that of the second transistor electrode E2.

The second interlayer insulating layer 123 may cover the first interlayer insulating layer 122, the first transistor electrode E1, and the second transistor electrode E2.

The planarization layer 124 may cover the second interlayer insulating layer 123 and include an organic insulating material.

The element layer 130 may be disposed on the planarization layer 124 of the circuit layer 120.

The element layer 130 includes light emitting elements LE in the light emission areas EA. The element layer 130 includes a light receiving portion B in the non-display area NDA.

Each of the light emitting elements LE may include a structure in which light emitting layers 133 are between a first light emitting electrode 131 and a second light emitting electrode 134, which face each other.

For example, the element layer 130 may include first light emitting electrodes 131 in the light emission areas EA on the circuit layer 120, a pixel defining layer 132 in the non-light emission area NEA on the circuit layer 120, covering edges of the first light emitting electrodes 131, a light emitting layer 133 on the first light emitting electrodes 131, and a second light emitting electrode 134 on the light emitting layer 133.

The light emitting layer 133 may be disposed in each of the light emission areas EA, and may be spaced apart from another one. A first light emitting layer 133_1 in the first light emission area EA1 may emit light of a first wavelength band. A second light emitting layer 133_2 in the second light emission area EA2 may emit light of a second wavelength band. A third light emitting layer 133_3 in the third light emission area EA3 may emit light of a third wavelength band.

The first light emitting electrodes 131 may be electrically connected to the light emitting pixel drivers EPD through an anode connection hole ANCH.

For example, the first light emitting electrode 131 may be electrically connected to the second transistor electrode E2 of the first transistor ST1 of the light emitting pixel driver EPD through the anode connection hole ANCH.

The anode connection hole ANCH may pass through the planarization layer 124 and the second interlayer insulating layer 123.

The first light emitting electrode 131 may be electrically conductive. The first light emitting electrode 131 may include a metal alloy or a conductive compound. The first light emitting electrode 131 may be an anode. The first light emitting electrode 131 may be a pixel electrode.

In the light emitting element LE, according to an embodiment, the first light emitting electrode 131 may be a reflective electrode, but the embodiment is not necessarily limited thereto. For example, the first light emitting electrode 131 may be a transmissive electrode or a semi-transmissive electrode. When the first light emitting electrode 131 is a semi-transmissive electrode or a reflective electrode, the first light emitting electrode 131 may include silver (Ag), magnesium (Mg), copper (Cu), aluminum (Al), platinum (Pt), palladium (Pd), gold (Au), nickel (Ni), neodymium (Nd), iridium (Ir), chromium (Cr), lithium (Li), calcium (Ca), lithium fluoride (LiF)/calcium (Ca), LiF/Al, molybdenum (Mo), titanium (Ti) or their compound or mixture (e.g., a mixture of Ag and Mg). Alternatively, the first light emitting electrode 131 may have a multi-layered structure that includes a reflective film or semi-transmissive film, which includes the above-exemplified materials, and a transparent conductive film that includes indium tin oxide (ITO), indium zinc oxide (IZO), zinc oxide (ZO), and indium tin zinc oxide (ITZO). For example, the first light emitting electrode 131 may be a multi-layered metal film, and may have a structure in which a metal film of ITO/Ag/ITO is stacked.

The pixel defining layer 132 may partition the first light emitting electrode 131 on the planarization layer 124, thereby defining the light emission areas EA1, EA2 and EA3. The pixel defining layer 132 may cover an edge of the first light emitting electrode 131. The pixel defining layer 132 may include an organic film such as an acrylic resin, an epoxy resin, a phenolic resin, a polyamide resin, and a polyimide resin.

The light emitting layer 133 may be in a light emission area partitioned by the pixel defining layer 132 on the first light emitting electrode 131. The light emitting layer 133 may include an organic material to emit light having a particular color. The light emitting layer 133 may emit light of various light emitting wavelengths depending on a type of the organic material. A hole layer HL may be disposed between the first light emitting electrode 131 and the light emitting layer 133. An electron layer EL may be disposed between the light emitting layer 133 and the second light emitting electrode 134.

The first light emitting layer 133_1 may include an organic material that emits light of a first wavelength band. The second light emitting layer 133_2 may include an organic material that emits light of a second wavelength band. The third light emitting layer 133_3 may include an organic material that emits light of a third wavelength band.

The first wavelength band may be a lower wavelength band than the second wavelength band, and the second wavelength band may be a lower wavelength band than the third wavelength band. For example, the first wavelength band may be a blue wavelength band, the second wavelength band may be a green wavelength band, and the third wavelength band may be a red wavelength band. For example, the blue wavelength band may indicate that a main peak wavelength of light is included in a wavelength band of about 370 nm to 460 nm, the green wavelength band may indicate that a main peak wavelength of light is included in a wavelength band of about 480 nm to 560 nm, and the red wavelength band may indicate that a main peak wavelength of light is included in a wavelength band of about 600 nm to 750 nm.

The second light emitting electrode 134 may be disposed in the display area DA, which includes light emission areas EA1, EA2 and EA3 (EA of FIG. 3) and a non-light emission area NEA, and a non-display area NDA. The second light emitting electrode 134 may be on the electron layer EL.

The second light emitting electrode 134 may be a common electrode or a cathode. The second light emitting electrode 134 may be a transmissive electrode, a semi-transmissive electrode, or a reflective electrode. When the second light emitting electrode 134 is a transmissive electrode, the second light emitting electrode 134 may include a transparent metal oxide, for example, indium tin oxide (ITO), indium tin oxide (ZO), zinc oxide (ZnO), indium tin zinc oxide (ITZO), or the like.

When the second light emitting electrode 134 is a semi-transmissive electrode or a reflective electrode, the second light emitting electrode 134 may include Ag, Mg, Cu, Al, Pt, Pd, Au, Ni, Nd, Ir, Cr, Li, Ca, LiF/Ca, LiF/Al, Mo, Ti, Yb or their compound (e.g., AgYb, or a compound of AgMg and MgAg depending on content) or their mixture (e.g., mixture of Ag and Mg). Alternatively, the second light emitting electrode 134 may have a multi-layered structure that includes a reflective film or semi-transmissive film containing the above materials, and a transparent conductive film containing indium tin oxide (ITO), indium zinc oxide (IZO), zinc oxide (ZnO), indium tin zinc oxide (ITZO), etc.

Thus, the display device may include a display area and a non-display area on a substrate, with the device capable of emitting images and incorporating various structural features like flexibility and different geometric shapes. The display area contains light-emitting elements composed of multiple layers, including electrodes, organic light-emitting materials, and insulating materials, which are arranged to produce light in specific color bands (e.g., blue, green, and red). The structure of the circuit and element layers and the materials used for electrodes and pixel definition is specially engineered so as to optimize light emission efficiency, enable precise color control, and support compact integration of driving circuits while maintaining mechanical flexibility and high display performance.

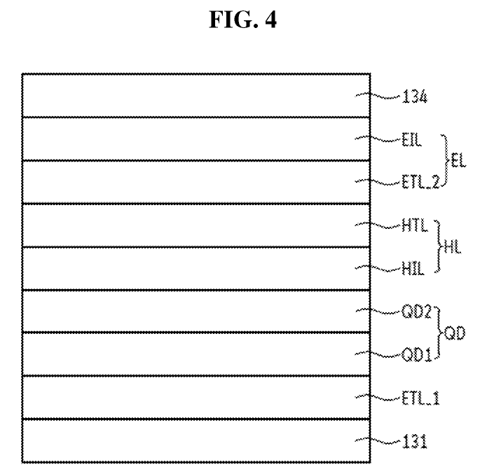

FIG. 4 is an enlarged cross-sectional view illustrating an area of a light receiving portion PD of FIG. 3.

The element layer 130 may include a light receiving portion PD in the non-display area NDA. The light receiving portion PD may include a first light emitting electrode 131, a first electron transport layer ETL_1, a quantum layer QD, a hole layer HL, an electron layer EL, and a second light emitting electrode 134.

The light receiving portion PD may absorb light having a wavelength of 600 nm to 950 nm and convert the light into an electrical signal. The light receiving portion PD may be utilized for an infrared sensor or a proximity sensor.

When the light receiving portion PD is stacked on a separate layer from the light emitting element LE, a process may be complicated. The present disclosure may simplify the process by arranging the light receiving portion PD in the non-display area NDA.

The display device 10 may include the light receiving portion PD, thereby implementing the display device 10, in which an infrared sensor or a proximity sensor is embedded. The display device 10 may include a camera. The light receiving portion PD may be near the camera.

The first electron transport layer ETL_1 may be an inorganic semiconductor. For example, the first electron transport layer ETL_1 may include Zn oxide (ZnO_{X}), Ti oxide (TiO_{X}), Sn oxide (SnO_{X}), Zr oxide (ZrO_{X}), or n-GaN. The first electron transport layer ETL_1 may transfer electrons transferred from the quantum layer QD to the first light emitting electrode 131. The first electron transport layer ETL_1 may prevent holes transferred from the quantum layer QD from being transferred to the first light emitting electrode 131.

The quantum layer QD may be disposed on the first light emitting electrode 131 of the non-display area NDA. The quantum layer may include a first quantum dot of N-type and a second quantum dot of a P-type. The first quantum dot and the second quantum dot may include a ligand. The ligand may include halogen, a thiol group, a hydroxyl group, or a carboxyl group. When synthesizing quantum dots, a carbon length of the ligand may be relatively long. When a ligand having a long carbon length is replaced with a short ligand such as halogen, a thiol group, a hydroxyl group, or a carboxyl group, conductivity may be provided to the quantum dots.

The first quantum dot and the second quantum dot may independently include at least one of indium arsenide (InAs), indium antimonide (InSb), lead sulfide (PbS), or silver telluride (Ag₂Te). The first quantum dot and the second quantum dot might not necessarily be limited to what is disclosed herein as long as they absorb light having a wavelength of 600 nm to 950 nm.

When the quantum dots are indium arsenide (InAs), since they have N-type properties, the first quantum dot might not be doped and the second quantum dot may be doped with P-type dopant. Zn may be used as the P-type dopant. When the quantum dots are lead sulfide (PbS), since they have P-type properties, the first quantum dot may be doped with N-type dopant and the second quantum dot might not be doped.

The quantum layer QD may absorb light having a wavelength of 600 nm to 950 nm and convert the light into an electrical signal. The quantum layer QD may be a layer in which the first quantum dot and the second quantum dot are mixed. Alternatively, the quantum layer QD may include a first quantum layer QD1 including the first quantum dot and a second quantum dot layer QD2 on the first quantum dot layer QD1, including the second quantum dot. The first quantum layer QD1 may have N-type electrical characteristics, and the second quantum layer QD2 may have P-type electrical characteristics. As the first quantum layer of N-type and the second quantum layer QD2 of P-type are subjected to junction, the light receiving portion PD may be driven in a diode type.

The quantum layer QD may have an external quantum efficiency of 40% or more at a wavelength of 600 nm to 950 nm.

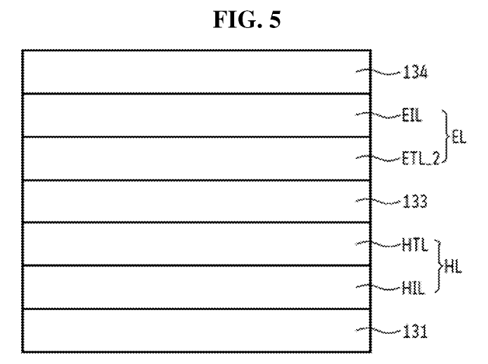

FIG. 5 is an enlarged cross-sectional view illustrating an area of a light emitting element LE of FIG. 3.

The hole layer HL is on the quantum layer QD, and may include a hole injection layer HIL and a hole transport layer HTL. The hole injection layer HIL may serve to more actively inject holes from the quantum layer QD to the second light emitting electrode 134. The hole layer HL may extend and be in the light emitting element LE of the display area DA as shown in FIG. 3. In the display area DA, the hole layer HL may be on the first light emitting electrode 131. In the light emitting element LE, the hole injection layer HIL may serve to more actively inject holes into the light emitting layer 133.

In some embodiments, the hole injection layer HIL may include one or more selected from a group consisting of copper phthalocyanine (CuPc), poly(3,4)-ethylenedioxythiophene (PEDOT), polyaniline (PANI), and N,N-dinaphthyl-N,N'-diphenyl benzidine (NPD), but is not necessarily limited thereto.

The hole transport layer HTL may be disposed on the hole injection layer HIL. The hole transport layer HTL serves to actively transport holes, and may include a hole transport material. The hole transport material may include a carbazole-based derivative such as N-phenylcarbazole and polyvinylcarbazole, a fluorene-based derivative, a triphenylamine-based derivative such as N,N'-bis(3-methylphenyl)-N,N'-diphenyl-[1,1-biphenyl]-4,4'-diamine (TPD) and 4,4',4"-tris(N-carbazolyl)triphenylamine (TCTA), N,N'-di(1-naphthyl)-N,N'-diphenylbenzidine (NPB), 4,4'-Cyclohexylidene bis[N,N-bis(4-methylphenyl)benzenamine] (TAPC), etc., but is not necessarily limited thereto.

The electron layer EL is disposed on the hole layer HL in the non-display area NDA, and may include a second electron transport layer ETL_2 and an electron injection layer EIL. The electron layer EL may extend and be in the light emitting element LE of the display area DA as shown in FIG. 3. In the display area DA, the electron layer EL may be disposed on the light emitting layer 133. In the light emitting element LE, the electron injection layer EIL may serve to more actively inject holes into the light emitting layer 133. The second electron transport layer ETL_2 serves to actively transport electrons, and may include an electron transport material.

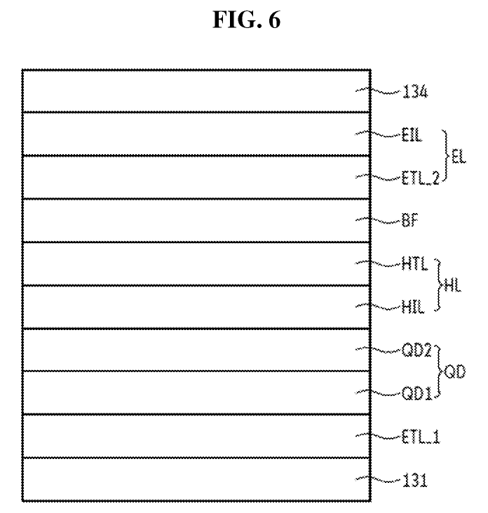

FIG. 6 is an enlarged cross-sectional view illustrating an area of a light receiving portion PD of the second embodiment of FIG. 3.

Referring to FIG. 6, the light receiving portion PD may further include a buffer layer BF. The buffer layer BF may be disposed between the hole layer HL and the electron layer EL, but is not necessarily limited thereto. The buffer layer BF may also be disposed between the second hole transport layer ETL_2 and the electron injection layer EIL or between the hole injection layer HIL and the hole transport layer HTL, depending on an energy level. The buffer layer BF may be intended to well transfer holes or electrons by light incident on the quantum layer QD to the first light emitting electrode 131 or the second light emitting electrode 134. In the area of the light emitting element LE, the buffer layer BF may be intended to well transfer holes or electrons to the light emitting layer 133.

The encapsulation layer 140 may include a first inorganic encapsulation layer 141 on the element layer 130, including an inorganic material, an organic encapsulation layer 142 on the first inorganic encapsulation layer 141, and a second inorganic encapsulation layer 143 on the organic encapsulation layer 142, including an inorganic material.

By the encapsulation layer 140, a defect of the circuit layer 120 or the element layer 130 due to particles may be reduced, and a defect in which oxygen or moisture is permeated into the circuit layer 120 or the element layer 130 may be delayed or prevented.

The encapsulation layer 140 may be disposed on the second light emitting electrode 134. Also, when the light emitting element LE according to an embodiment includes a capping layer, the encapsulation layer 140 may disposed be on the capping layer.

The encapsulation layer 140 may be formed by stacking a plurality of layers. The encapsulation layer 140, according to an embodiment, may include at least one organic layer (hereinafter, referred to as an organic encapsulation layer) and at least one inorganic layer (hereinafter, referred to as an inorganic encapsulation layer).

The first inorganic encapsulation layer 141 may be disposed on the second light emitting electrode 134. When the light emitting element LE further includes a capping layer, the first inorganic encapsulation layer 141 may be on the capping layer.

The first inorganic encapsulation layer 141 may serve to protect the light emitting element LE from moisture and oxygen. The first inorganic encapsulation layer 141 includes an inorganic material to have a high film density, and may have a large bond with a functional layer below the first inorganic encapsulation layer 141. Thus, moisture or oxygen may be prevented from being permeated into an interface between the first inorganic encapsulation layer 141 and the functional layer below the first inorganic encapsulation layer 141, for example, the second light emitting electrode 134 or the capping layer. Also, peeling of the first inorganic encapsulation layer 141 may be prevented. The first inorganic encapsulation layer 141 may include at least one of silicon nitride, silicon oxynitride, silicon oxide, titanium oxide, or aluminum oxide.

The organic encapsulation layer 142 may be disposed on the first inorganic encapsulation layer 141. The organic encapsulation layer 142 may serve to protect the display device 10 from particles such as dust particles. The organic encapsulation layer 142 may have a flat upper surface. The organic encapsulation layer 142 may reduce a step difference of the first inorganic encapsulation layer 141. The organic encapsulation layer 142 may reduce a step difference of an upper surface of the first inorganic encapsulation layer 141 so that a functional layer may be uniformly disposed above the organic encapsulation layer 142. In an embodiment, a thickness of the organic encapsulation layer 142 may be greater than a thickness of the first inorganic encapsulation layer 141. Also, the thickness of the organic encapsulation layer 142 may be greater than the thickness of the first inorganic encapsulation layer 141 and a thickness of the second inorganic encapsulation layer 143. The organic encapsulation layer 142 may include a polymer resin.

The second inorganic encapsulation layer 143 may be disposed on the organic encapsulation layer 142. The second inorganic encapsulation layer 143 may include an inorganic material. The second inorganic encapsulation layer 143 may protect the display device 10 from moisture and oxygen. The second inorganic encapsulation layer 143 may prevent moisture and oxygen from being permeated into the interface between the second inorganic encapsulation layer 143 and the organic encapsulation layer 142 due to a high bonding force with the organic encapsulation layer 142.

The encapsulation layer 140 may further include an additional organic encapsulation layer and an additional inorganic encapsulation layer, which are disposed on the second inorganic encapsulation layer 143. The encapsulation layer 140 may further include ‘n’ number of additional organic encapsulation layers and ‘n’ number of additional inorganic encapsulation layers, where ‘n’ is a positive integer. The ‘n’ number of additional organic encapsulation layers and the ‘n’ number of additional inorganic encapsulation layers may be alternately arranged. On average, the ‘n’ number of additional organic encapsulation layers may have greater thicknesses than the ‘n’ number of additional inorganic encapsulation layers, but the embodiment is not necessarily limited thereto. The description of the organic encapsulation layer 142, the first inorganic encapsulation layer 141, and the second inorganic encapsulation layer 143 may be equally applied to materials of the additional organic encapsulation layer and the additional inorganic encapsulation layer.

Thus, a light receiving portion integrated into the non-display area of a display device uses a layered structure of electrodes, transport layers, and a quantum dot layer composed of N-type and P-type quantum dots to absorb near-infrared light and convert it into electrical signals for functions like proximity or infrared sensing. These quantum dots are engineered for conductivity via ligand exchange and doping, and are configured in either mixed or stacked layers to create diode-like behavior with high external quantum efficiency. The light receiving and emitting structures share common layers, and the entire device is protected by a multilayer encapsulation system composed of alternating organic and inorganic materials designed to shield internal components from moisture, oxygen, and particulates.

A method for manufacturing the light receiving portion PD and the light emitting element LE will be described below.

First, the first light emitting electrode 131 may be formed in first and second areas on a substrate SUB including the first and second areas. The first area may be the non-display area NDA, and the second area may be the display area DA. The first light emitting electrode 131 may be formed using the above-exemplified material, and a process method used for forming the first light emitting electrode 131 is not necessarily limited.

Subsequently, the pixel defining layer 132 may be formed on the substrate SUB including the first light emitting electrode 131. By forming the pixel defining layer 132, each light emission area and light receiving area may be partitioned. The pixel defining layer 132 may be formed using the above-exemplified material, and a process method used for forming the pixel defining layer 132 is not necessarily limited.

Subsequently, a first electron transport layer ETL_1 may be formed on the non-display area NDA of the first light emitting electrode 131. The first electron transport layer ETL_1 may be formed using the above-exemplified materials, and a process method used for forming the first electron transport layer ETL_1 is not necessarily limited.

Subsequently, a quantum layer QD may be formed on the non-display area NDA of the first electron transport layer ETL_1. The step of forming the quantum layer QD may include forming the quantum layer QD by mixing a first quantum dot with a second quantum dot. Alternatively, the step of forming the quantum layer QD may include a step of forming a first quantum layer QD1 including the first quantum dot, and a step of forming a second quantum dot layer QD2 including the second quantum dot on the first quantum layer QD1. The quantum layer QD may be formed using the above-exemplified material, and a process method used for forming the quantum layer QD is not necessarily limited.

The step of forming the quantum layer QD may include a step of synthesizing the first quantum dot with the second quantum dot, a step of doping the first quantum dot or the second quantum dot with a dopant, and a step of exchanging ligands of the first quantum dot and the second quantum dot. The quantum dot layer QD may be formed by mixing the first quantum dot and the second quantum dot, in which the ligands are exchanged, the first quantum layer QD1 including the first quantum dot may be formed, or the second quantum layer QD1 including the second quantum dot may be formed on the first quantum layer QD1.

Subsequently, the hole layer HL may be formed on the non-display area NDA of the quantum layer QD and the display area DA of the first light emitting electrode 131. The step of forming the hole layer HL may include a step of forming the hole injection layer HIL and a step of forming the hole transport layer HTL. The hole layer HL may be formed using the above-exemplified material, and a process method used for forming the hole layer HL is not necessarily limited. The hole layer HL may be formed as a common layer on the light receiving portion PD of the non-display area NDA and the light emitting element LE of the display area DA.

Subsequently, the light emitting layer 133 may be formed on the display area DA of the hole layer HL. The light emitting layer 133 may be formed using the above-exemplified material, and a process method used for forming the light emitting layer 133 is not necessarily limited.

Subsequently, the electron layer EL may be formed on the non-display area NDA of the hole layer HL and the display area DA of the light emitting layer 133. The step of forming the electron layer EL may include a step of forming the second electron transport layer ETL_2 and a step of forming the electron injection layer EIL. The electron layer EL may be formed using the above-exemplified material, and a process method used for forming the electron layer EL is not necessarily limited. The electron layer EL may be formed as a common layer on the light receiving portion PD of the non-display area NDA and the light emitting element LE of the display area DA.

Since the hole layer HL and the electron layer EL may be formed as common layers on the light receiving portion PD of the non-display area NDA and the light emitting element LE of the display area DA, the process may be more simplified than the case that the light receiving portion PD and the light emitting element LE are stacked.

The method for manufacturing the display device 10 may further include a step of forming a buffer layer BF. The buffer layer BF may be formed on the quantum layer QD, the hole injection layer HIL, the hole transport layer HTL, the second electron transport layer ETL_2, or the electron injection layer EIL. In some cases, two or more buffer layers BF may be stacked.

Subsequently, the second light emitting electrode 134 may be formed on the non-display area NDA and the display area DA of the electron layer EL. The second light emitting electrode 134 may be formed using the above-exemplified material, and a process method used for forming the second light emitting electrode 134 is not necessarily limited to the approach described above.

Although the present disclosure will be described in more detail through the following embodiments, the following embodiments are intended for description and are not necessarily intended to limit the scope of the present disclosure.

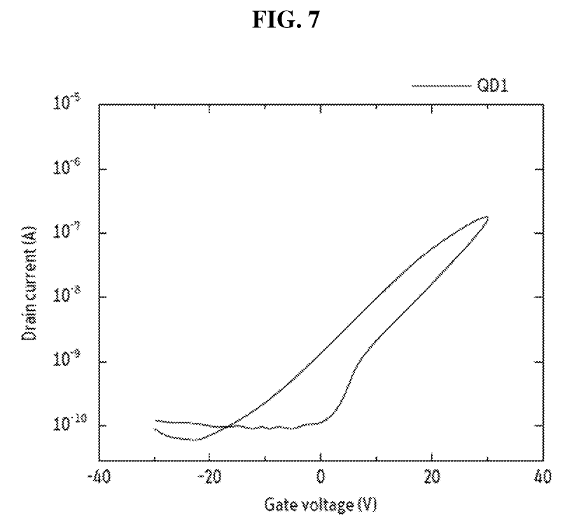

FIG. 7 is a graph illustrating electrical characteristics when a first quantum dot is applied to a field effect transistor.

In FIG. 7, indium arsenide (InAs) in which a ligand is exchanged with bromine (Br) is used as the first quantum dot. When indium arsenide (InAs), in which the ligand is exchanged with bromine (Br), is applied to a field effect transistor (FET), it may be noted that N-type electrical characteristics in which a current increases as a voltage increases are exhibited.

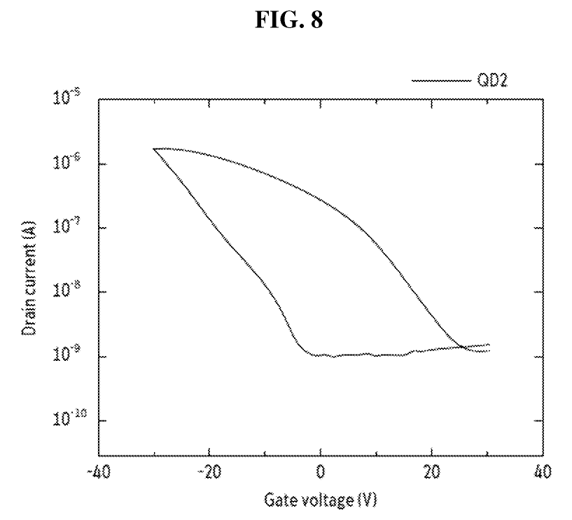

FIG. 8 is a graph illustrating electrical characteristics when a second quantum dot is applied to a field effect transistor.

In FIG. 8, indium arsenide (InAs) doped with zinc, in which a ligand is exchanged with chlorine (Cl), is used as the second quantum dot. When indium arsenide (InAs) doped with zinc, in which a ligand is exchanged with chlorine (Cl), is applied to a field effect transistor, it may be noted that P-type electrical characteristics in which a current increases as a voltage increases are exhibited.

### Example 1

ITO was formed on a substrate as a first electrode, ZnO was formed on ITO as a first electron transport layer, indium arsenide (InAs), in which a ligand was exchanged with bromine (Br), was formed on ZnO as a first quantum layer, indium arsenide (InAs) doped with zinc (Zn), in which a ligand was exchanged with chlorine (Cl), was formed on the first quantum layer as a second quantum layer, a hole injection layer and a hole transport layer were formed on the second quantum layer, an electron injection layer and a second electron transport layer were formed on the hole injection layer and the hole transport layer, and aluminum was formed on the electron injection layer and the second electron transport layer as a second electrode, whereby a light receiving portion was manufactured.

### Comparative Example 1

A light receiving portion QD1 was manufactured in the same manner as the light receiving portion of Example 1, except that only a first quantum layer was formed as the quantum layer.

### Comparative Example 2

A light receiving portion QD2 was manufactured in the same manner as the light receiving portion of Example 1, except that only a second quantum layer was formed as the quantum layer.

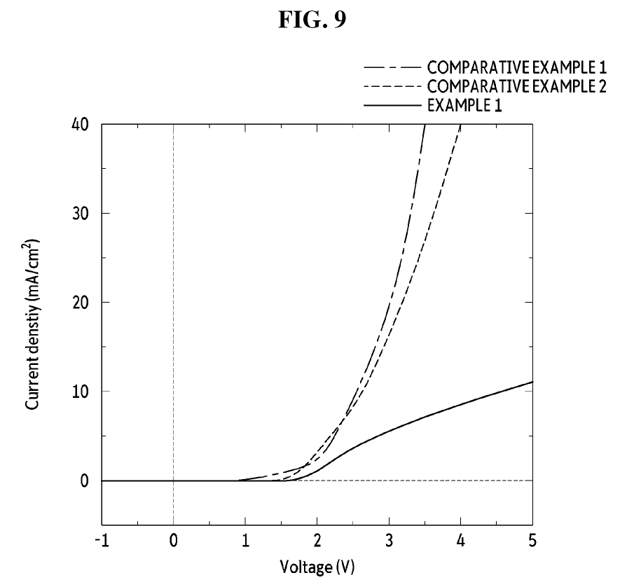

FIG. 9 is a graph illustrating electrical characteristics when light is directed to a light receiving portion of Comparative Example 1, Comparative Example 2, and Example 1.

In detail, FIG. 9 shows a voltage-current graph when light of 100 mW/cm² is directed to a light receiving portion. According to the results shown in FIG. 9, it may be noted that electric conduction occurs in the light receiving portion in which the first quantum layer or the second quantum layer is manufactured as a single layer. On the other hand, it may be noted that Example 1 formed by bonding the first quantum layer to the second quantum layer indicates a diode type.

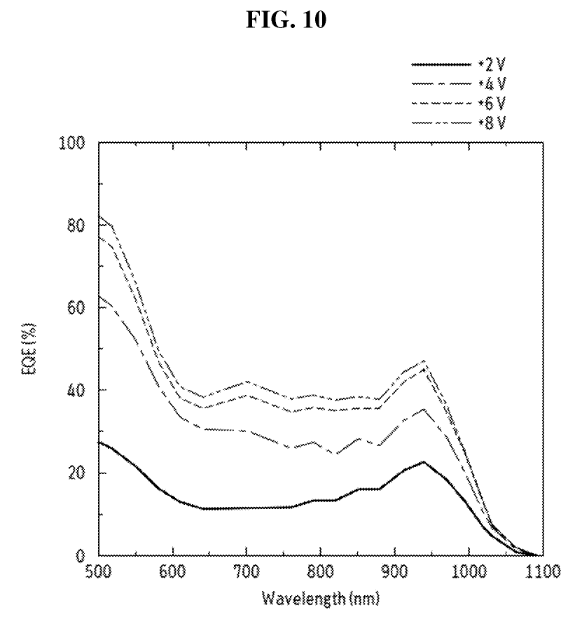

FIG. 10 is a graph illustrating external quantum efficiency (EQE) according to a wavelength of Example 1 manufactured in accordance with the embodiment.

According to the results shown in FIG. 10, it may be noted that external quantum efficiency increases as a voltage increases, and the highest external quantum efficiency is shown in a near-infrared area (940 nm). It may be noted that external quantum efficiency at a wavelength of 940 nm under a voltage of 6V is 47%.

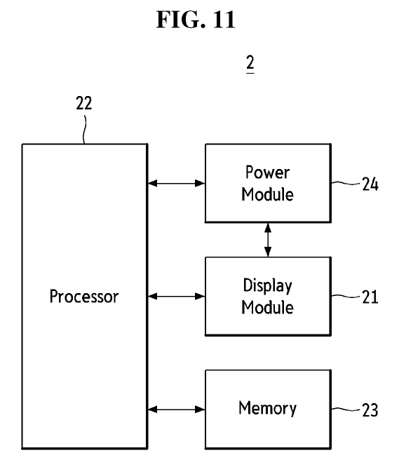

FIG. 11 is a block diagram illustrating an electronic device according to an embodiment. Referring to FIG. 11, an electronic device 2, according to an embodiment, may include a display module 21, a processor 22, a memory 23, and a power module 24.

The processor 22 may include at least one of a central processing unit (CPU), an application processor (AP), a graphic processing unit (GPU), a communication processor (CP), an image signal processor (ISP), or a controller.

Data information required for an operation of the processor 22 or the display module 21 may be stored in the memory 23. When the processor 22 executes an application stored in the memory 23, an image data signal and/or an input control signal is transmitted to the display module 21, and the display module 21 may process the received signal and output image information through a display screen.

The power module 24 may include a power supply module such as a power adapter or a battery device, and a power conversion module that converts a power source supplied by the power supply module to generate a power source required for the operation of the electronic device 2.

At least one of the respective components of the above-described electronic device 2 may be included in the display device 10 according to the above-described embodiments. Also, some of the individual modules functionally included in one module may be included in the display device 10, and others thereof may be provided separately from the display device 10. For example, the display device 10 includes the display module 21, and the processor 22, the memory 23 and the power module 24 may be provided as other devices in the electronic device 2 not the display device 10.

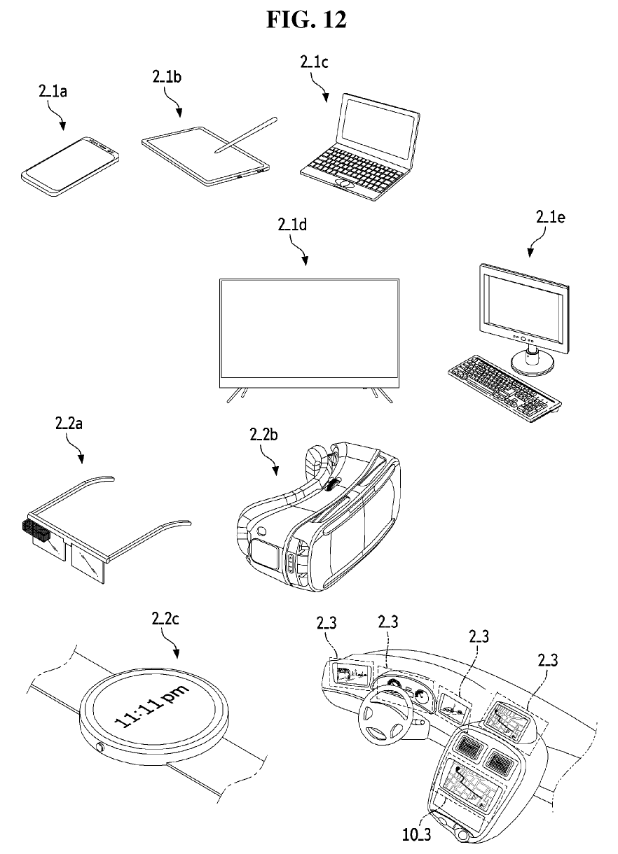

FIG. 12 illustrates schematic diagrams of electronic devices according to various embodiments.

Referring to FIG. 12, various electronic devices 2 to which the display devices according to the embodiments are applied may include not only electronic devices for image display, such as a smart phone 2_1a, a tablet 2_1b, a laptop/notebook 2_1c,a TV 2_1d, and a computer monitor 2_1e, but also wearable electronic devices including display modules such as smart glasses 2_2a, a head mounted display 2_2b, and a smart watch 2_2c, and a vehicle electronic device 2_3 including display modules such as a vehicle dashboard, a center fascia, a center information display (CID) on the dashboard, and a room mirror display.

Although the embodiments of the present invention have been described with reference to the attached drawings, those skilled in the art will understand that the present invention can be implemented in other specific forms without changing the technical idea or essential features of the present invention. Therefore, it should be understood that the embodiments described above are exemplary in all respects and not necessarily restrictive.

What is claimed is:

1. A display device, comprising:
a substrate comprising a first area and a second area;
a first electrode disposed in the first area and the second area of the substrate;
a first electron transport layer disposed in the first area of the substrate, on the first electrode;
a quantum layer disposed in the first area of the substrate, on the first electron transport layer;
a hole layer disposed in the first area of the substrate, on the quantum layer, and further disposed in the second area of the substrate, on the first electrode;
a light emitting layer disposed in the second area of the substrate, on the hole layer;
an electron layer disposed in the first area of the substrate, on the hole layer, and further disposed in the second area of the substrate, on the light emitting layer; and
a second electrode disposed in the first area of the substrate, on the electron layer, and further disposed on the second area of the substrate, on the electron layer,
wherein the quantum layer comprises a first quantum dot of N type and a second quantum dot of P type.

2. The display device of claim 1, wherein the quantum layer comprises a first quantum layer comprising the first quantum dot, and a second quantum dot layer disposed on the first quantum layer, comprising the second quantum dot.

3. The display device of claim 1, wherein the quantum layer is configured to absorb light having a wavelength of 600 nm to 950 nm and is configured to convert the absorbed light into an electrical signal.

4. The display device of claim 3, wherein the quantum layer has external quantum efficiency of 40% or more at a wavelength of 600 nm to 950 nm.

5. The display device of claim 1, wherein the first quantum dot and the second quantum dot each comprise a ligand, and the ligand comprises halogen, a thiol group, a hydroxyl group, or a carboxyl group.

6. The display device of claim 1, wherein each of the first quantum dot and the second quantum dot comprises at least one of indium arsenide (InAs), indium antimonide (InSb), lead sulfide (PbS), or silver telluride (Ag₂Te).

7. The display device of claim 6, wherein the first quantum dot or the second quantum dot is doped with a dopant.

8. The display device of claim 1, wherein the first area is a light receiving portion that is configured to absorb light having a wavelength of 600 nm to 950 nm, and the second area is a light emitting portion that is configured to emit light.

9. The display device of claim 8, wherein the second area is configured to emit light having a wavelength of 350 nm to 800 nm.

10. The display device of claim 1, wherein the first area is a non-display area, and the second area is a display area.

11. The display device of claim 1, wherein the hole layer comprises a hole injection layer and a hole transport layer disposed on the hole injection layer.

12. The display device of claim 1, wherein the electron layer comprises a second electron transport layer and an electron injection layer disposed on the second electron transport layer.

13. The display device of claim 1, further comprising a buffer layer disposed between the electron layer and the hole layer.

14. A method for manufacturing a display device, the method comprising:
forming a first electrode in a first area and a second area of a substrate;
forming a first electron transport layer in the first area of the substrate, on the first electrode;
forming a quantum layer in the first area of the substrate, on the first electron transport layer;
forming a hole layer in the first area of the substrate, on the quantum layer, and forming the hole layer on the second area of the substrate, on the first electrode;
forming a light emitting layer in the second area of the substrate, on the hole layer;
forming an electron layer in the first area of the substrate, on the hole layer, and forming the electron layer in the second area of the substrate, on the light emitting layer; and
forming a second electrode in the first area of the substrate, and forming the second electrode in the second area of the substrate, on the electron layer,
wherein the quantum layer comprises a first quantum dot of N type and a second quantum dot of P type.

15. The method of claim 14, wherein the forming a quantum layer comprises:
forming a first quantum layer comprising the first quantum dot; and
forming a second quantum dot layer comprising the second quantum dot on the first quantum layer.

16. The method of claim 14, wherein the first quantum dot and the second quantum dot each comprise a ligand, and the ligand comprises halogen, a thiol group, a hydroxyl group, or a carboxyl group.

17. An electronic device, comprising:
a display device displaying an image; and
a processor transmitting an image data signal to the display device,
wherein the display device comprises:
a substrate comprising a first area and a second area;
a first electrode disposed in the first area and the second area of the substrate;
a first electron transport layer disposed in the first area of the substrate, on the first electrode;
a quantum layer disposed in the first area of the substrate, on the first electron transport layer;
a hole layer disposed in the first area of the substrate, on the quantum layer, and further disposed in the second area of the substrate, on the first electrode;
a light emitting layer disposed in the second area of the substrate, on the hole layer;
an electron layer disposed in the first area of the substrate, on the hole layer, and further disposed in the second area of the substrate, on the light emitting layer; and
a second electrode disposed in the first area of the substrate, and further disposed in the second area of the substrate, on the electron layer,
wherein the quantum layer comprises a first quantum dot of N type and a second quantum dot of P type.

18. The electronic device of claim 17, wherein the quantum layer comprises a first quantum layer comprising the first quantum dot, and a second quantum dot layer disposed on the first quantum layer, comprising the second quantum dot.

19. The electronic device of claim 17, wherein the first quantum dot and the second quantum dot each comprise a ligand, and the ligand comprises halogen, a thiol group, a hydroxyl group, or a carboxyl group.

20. The electronic device of claim 17, wherein the first area is a non-display area, and the second area is a display area.
